(19) United States
(12) Patent Application Publication
(10) Pub. No.: US 2015/0376772 A1
(43) Pub. Date: Dec. 31, 2015

(54) MULTI-SURFACE NANOPARTICLE SOURCES AND DEPOSITION SYSTEMS

(71) Applicant: REGENTS OF THE UNIVERSITY OF MINNESOTA, St. Paul, MN (US)

(72) Inventors: Jian-Ping Wang, Shoreview, MN (US); Claire Hovland, Andover, MN (US); Shihai He, Minneapolis, MN (US)

(21) Appl. No.: 14/765,284

(22) PCT Filed: Jan. 31, 2014
(86) PCT No.: PCT/US2014/014264

§ 371 Date: Jul. 31, 2015

Related U.S. Application Data
(60) Provisional application No. 61/759,678, filed on Feb. 1, 2013.

(51) Int. Cl. C23C 14/34; H01J 37/34

(52) U.S. Cl. CPC C23C 14/34; H01J 37/342; H01J 37/3426

(57) ABSTRACT

A multi-surface nanoparticle source includes a first end having an inlet configured to receive a flow of gas, a second end comprising an outlet through which nanoparticles exit the nanoparticle source, and two or more targets spaced apart and arranged about an axis extending from the first end to the second end. At least at least one of the targets is hollow, and the inlet is arranged to direct a flow of the gas through the hollow target, between at least two of the targets, or both. The gas impacts the targets, releasing atoms from the target and through the second end. The targets may be arranged lengthwise and concentrically about the axis. In some cases, a multi-surface nanoparticle source includes one or more magnets. Nanoparticles formed with a multi-surface nanoparticle deposition system may be homogeneous or have a core-shell structure.

### CROSS-REFERENCE TO RELATED APPLICATION

This application claims priority to U.S. Appl. Ser. No. 61/759,678 entitled “MULTI-SURFACE NANOPARTICLE DEPOSITION SYSTEMS,” filed on Feb. 1, 2013, which is incorporated herein by reference in its entirety.

### TECHNICAL FIELD

This document relates to multi-surface nanoparticle deposition systems.

### BACKGROUND

Nanoparticles have many applications, including applications in the field of medicine. There are various ways of creating nanoparticles.

### SUMMARY

In a first general aspect, a nanoparticle source includes a first end having an inlet configured to receive a flow of gas, a second end comprising an outlet through which nanoparticles exit the nanoparticle source, and two or more targets spaced apart and arranged about an axis extending from the first end to the second end. At least one of the targets is hollow, and the inlet is arranged to direct a flow of the gas through the hollow target, between at least two of the targets, or both. The gas impacts the targets, releasing atoms from the target and through the second end of the nanoparticle source. The targets may be arranged lengthwise from the first end to the second end of the nanoparticle source, and may be arranged concentrically about the axis.

Implementations may include one or more of the following features.

In some cases, the aspect ratio of at least one of the targets is 1:1 or less (e.g., 1:2 or less, 1:4 or less, 1:6 or less, 1:8 or less, 1:10 or less, or 1:16 or less. In certain cases, the aspect ratio is 1:32 or greater. In some examples, the aspect ratio of at least one of the targets is in a range between 1:1 and 1:32 inclusive, in a range between 1:2 and 1:16 inclusive, in a range between 1:4 and 1:10 inclusive, or in a range between 1:6 and 1:8 inclusive.

In certain cases, the nanoparticle source includes a magnet proximate the second end of the nanoparticle source. The magnet is arranged to provide a magnetic field that controls movement of the gas through the nanoparticle source. The magnet may be coupled to an end of one of the targets. In some cases, the magnet forms an extension of the target to which it is coupled. The magnet may be a circular magnet having the same shape (e.g., same inner diameter and outer diameter) as the target to which the magnet is coupled. In certain cases, the magnet is a circular magnet, and an inner diameter of the circular magnet is greater than or equal to the outer diameter of the target to which the circular magnet is coupled. The magnet may include materials such as, for example, samarium cobalt, neodymium cobalt, or a combination thereof.

The targets may be arranged concentrically about the axis. In some cases, the targets define an opening between the targets, and the inlet is arranged to deliver a flow of gas through the opening and toward the second end of the nanoparticle source. In certain cases, one of the targets is a cylinder centered lengthwise about the axis. One or more of the targets may be tube targets. The targets may include a single target material or two or more target materials. In some cases, at least two of the targets include different target materials. In certain cases, at least one of the targets includes segments of two or more different target materials. The target materials may include, for example, Au, Ag, Fe, FeCo, Gd, SiO₂, Si, C, N, Al, Mg, or a combination thereof.

Some implementations include a cooling block, and at least some of the targets may be positioned in openings defined by the cooling block. The cooling block may be, for example, rectangular, cylindrical, or tubular. A surface of the cooling block (e.g., an inner surface or an outer surface of a tubular cooling block) may form a target. The target may include, for example, Au, Fe, Co, Ni, Si, Ti, N, Mg, C, or any combination thereof. In some cases, the cooling block defines a cooling chamber configured to receive a cooling fluid. The cooling block defines openings, and targets are positioned in the openings defined in the cooling block. The openings may form an array or one or more rings in the cooling block. The targets may be tube targets. The targets may be positioned in the openings defined by the cooling block and arranged in an array or in one or more concentric rings about the axis.

A nanoparticle source may include two or more cooling blocks. Each cooling block may be independently cooled. When the cooling block is rectangular, the nanoparticle source may include one or more additional rectangular cooling blocks and additional targets, wherein each additional rectangular cooling block defines additional openings, and the additional targets are positioned in the additional openings. Each additional rectangular cooling block may be positioned adjacent at least one other rectangular cooling block. When the cooling block is cylindrical or tubular, the nanoparticle source may include one or more additional tubular cooling blocks and additional tube targets, and each additional tubular cooling block may be arranged concentrically about a central cylindrical or tubular cooling block. Each additional tubular cooling block may define additional openings, and additional tube targets may be positioned in the additional openings and arranged (e.g., in one or more concentric rings) about the axis.

In some cases, the nanoparticle source includes a coil positioned about the nanoparticle source. The coil includes a current inlet and a current outlet and is configured to generate a magnetic field in each of the targets.

A second general aspect includes nanoparticles formed by any one of the nanoparticle sources described herein. In some cases, the nanoparticles are homogenous. In certain cases, the nanoparticles include a core and a shell. The core and the shell may include different materials, such as Fe, FeCo, Au, SiO₂, Fe₅Si₃, Fe₃Si, Fe₁₆N₂, FeN, or a combination thereof.

A third general aspect includes use of any one of the nanoparticle sources described herein to form nanoparticles.

A fourth general aspect includes forming nanoparticles by introducing a sputtering gas into any of the nanoparticle sources described herein via the inlet, ionizing the gas, and passing the ionized gas through a plasma region in the opening(s) between adjacent targets or through the targets to liberate atoms from the target, thereby yielding a gas comprising the liberated atoms. The gas including the liberated atoms is condensed to yield nanoparticles.

Implementations can provide any or all of the following advantages. Creation of nanoparticles can be improved. Nanoparticles of heterogeneous structure can be generated more efficiently and on a larger scale.

The details of one or more implementations are set forth in the accompanying drawings and the description below. Other features and advantages will be apparent from the description and drawings, and from the claims.

### DESCRIPTION OF DRAWINGS

FIG. 1 shows a cross-sectional view of an example multi-surface nanoparticle deposition system.

FIG. 2 shows a cross-section of the multi-surface nanoparticle deposition system in FIG. 1.

FIG. 3 shows an example of a pressure calculation.

FIG. 4 shows an alternative cross-section of the multi-surface nanoparticle deposition system in FIG. 1.

FIG. 5 shows a cross-sectional view of another example multi-surface nanoparticle deposition system.

FIG. 6 shows a cross-sectional view of another example multi-surface nanoparticle deposition system.

FIG. 7 shows a cross-sectional view of another example multi-surface nanoparticle deposition system.

FIGS. 8A-B show an example of a slot configuration in a multi-surface nanoparticle deposition system.

FIG. 9 shows an elevated view of another example of a multi-surface nanoparticle deposition system.

FIG. 10 shows a side view of the multi-surface nanoparticle deposition system in FIG. 9.

FIG. 11 shows an example of a multi-surface nanoparticle deposition system having a cylinder-shaped cooling block.

FIG. 12 shows a front view of a multi-surface nanoparticle deposition system in FIG. 11.

FIG. 13 shows a rear view of the multi-surface nanoparticle deposition system in FIG. 11.

FIG. 14 shows an example of a multi-surface nanoparticle deposition system having multiple cylinder-shaped cooling blocks.

FIG. 15 shows a front view of a multi-surface nanoparticle deposition system having multiple cylinder-shaped cooling blocks.

FIG. 16 shows a rear view of the multi-surface nanoparticle deposition system in FIG. 15.

FIG. 17 shows an example of a multi-surface nanoparticle deposition system having a multi-surface target and a multi-tube target.

FIG. 18 shows a front view of the multi-surface nanoparticle deposition system in FIG. 17.

FIG. 19 shows a rear view of the multi-surface nanoparticle deposition system in FIG. 17.

FIG. 20 shows an example of a multi-surface nanoparticle deposition system having a cube-shaped cooling block.

FIG. 21 shows a front view of the multi-surface nanoparticle deposition system in FIG. 20.

FIG. 22 shows a rear view of the multi-surface nanoparticle deposition system in FIG. 20.

FIG. 23 shows an example of a multi-surface nanoparticle deposition system having multiple cube-shaped cooling blocks.

FIG. 24 shows a front view of the multi-surface nanoparticle deposition system in FIG. 23.

FIG. 25 shows a rear view of the multi-surface nanoparticle deposition system in FIG. 23.

FIG. 26 shows an example of a multi-surface nanoparticle deposition system having a magnetic field supply.

FIG. 27 shows a front view of the multi-surface nanoparticle deposition system in FIG. 26.

FIG. 28 shows a cross-section of the multi-surface nanoparticle deposition system in FIG. 26.

FIG. 29 shows an example of a magnetic field configuration for a tube target.

### DETAILED DESCRIPTION

This document describes multi-surface nanoparticle sources and deposition systems and methods that are scalable for mass production. As described herein, a multi-surface nanoparticle source has two or more internal targets, so that the nanoparticle source has multiple surfaces. At least one of the targets is hollow. As used herein, a “hollow” target generally refers to a target having a lengthwise opening, such that a gas provided to a first end of the target flows lengthwise through the target and out a second end of the target. A “tube” target generally refers to a cylindrical target having a lengthwise opening, such that gas provided to a first end of the tube target flows lengthwise through the tube target and out a second end of the tube target.

A multi-surface nanoparticle source includes a first end having an inlet configured to receive a flow of gas, a second end comprising an outlet through which nanoparticles exit the multi-surface nanoparticle source, and two or more targets spaced apart and arranged about an axis extending from the first end to the second end of the multi-surface nanoparticle source. The targets may be arranged concentrically about the axis. At least one of the targets is hollow, and the inlet is arranged to direct a flow of the gas through the hollow target, between at least two of the targets, or both, such that the gas impacts the targets and releases atoms from the targets. The atoms exit the multi-surface nanoparticle source through the second end.

In more detail, inside multi-surface nanoparticle sources, target atoms are ejected from the targets due to the bombardment of argon ions which are generated by the ionization of argon gas (e.g., the supplied sputtering gas). The sputtered atoms form atom gas, and the gas condenses to form nanoparticles. The formed nanoparticles can be carried with a carrier gas and deposited on any suitable substrate of a nanoparticle collection device, including nanoparticle-assembled films.

Sputtering inside the targets and controlling the direction of movement of the nanoparticles can facilitate an automatic nanoparticle collection setup and handling process. Multi-part (e.g., two-part, three-part, or four-part) cooling systems can cool the targets during the sputtering/deposition process.

The systems described in this document can use gas phase condensation techniques based on one or more sputtering sources to fabricate several kinds of nanoparticles, including, but not limited to, heterostructured (e.g., core-shell) nanoparticles such as FeCo—Au, FeCo—SiO₂, Fe—Au, Fe—SiO₂, Fe₅Si₃—Au, Fe₅Si₃—SiO₂, and Fe₁₆N₂—Fe(N), to name a few examples.

In some cases, the aspect ratio of at least one of the targets is 1:1 or less (e.g., 1:2 or less, 1:4 or less, 1:6 or less, 1:8 or less, 1:10 or less, or 1:16 or less. In certain cases, the aspect ratio is 1:32 or greater. In some examples, the aspect ratio of at least one of the targets is in a range between 1:1 and 1:32 inclusive, in a range between 1:2 and 1:16 inclusive, in a range between 1:4 and 1:10 inclusive, or in a range between 1:6 and 1:8 inclusive.

In certain cases, a multi-surface nanoparticle source includes a magnet proximate the second end of the nanoparticle source. The magnet provides a magnetic field that controls movement of the ionized gas through the nanoparticle source. The magnet may be coupled to an end of one of the targets. In one example, a magnet coupled to an end of a target forms an extension of the target. In some instances, the magnet is a circular or ring magnet having the same inner diameter and outer diameter as the target to which the magnet is coupled. In some instances, the magnet is a circular or ring magnet, and an inner diameter of the ring magnet is greater than the outer diameter of the target to which the circular or ring magnet is coupled. A magnet may include, for example, samarium cobalt, neodymium cobalt, or a combination thereof.

A multi-surface nanoparticle deposition system may include one or more nanoparticle sources (e.g., one or more multi-surface nanoparticle sources) and a nanoparticle collection device housed in a vacuum chamber.

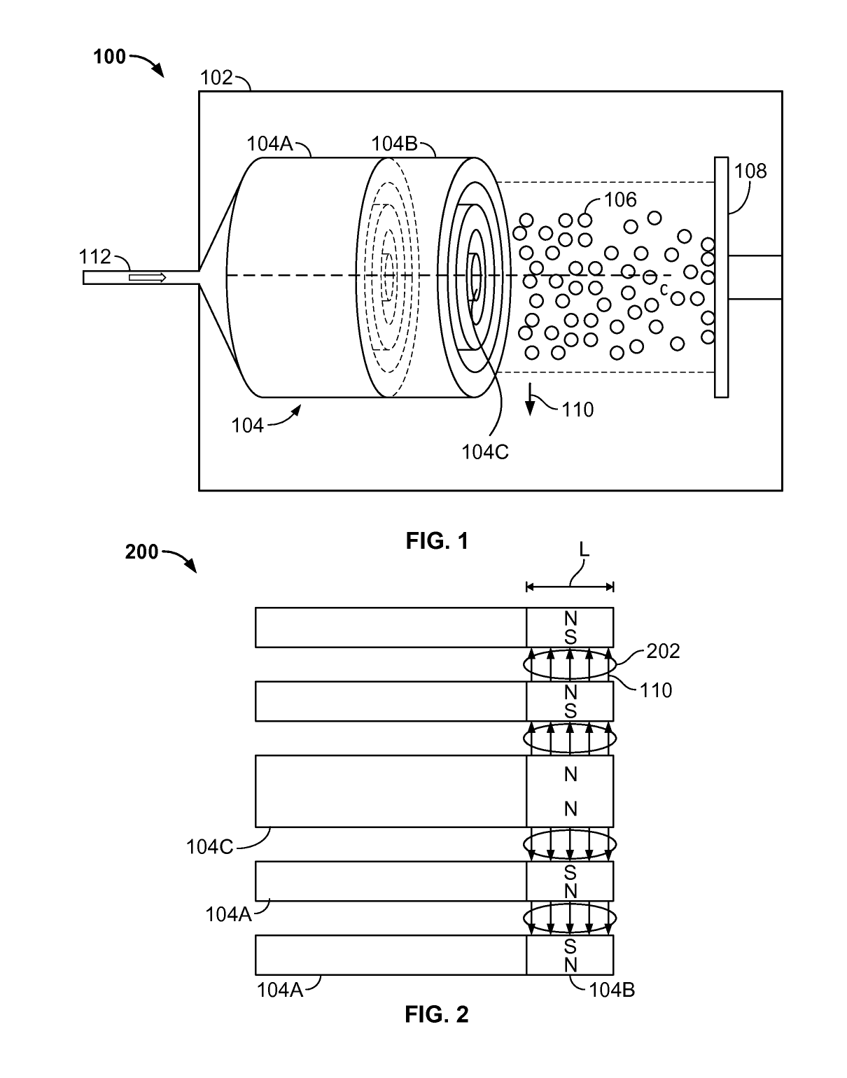

FIG. 1 shows a cross-sectional view of an example multi-surface nanoparticle deposition system 100. The system 100 includes a vacuum chamber 102 and a nanoparticle source 104. In operation, the source 104 will generate nanoparticles 106 that impinge on a nanoparticle collection substrate 108. A magnetic field 110 can be provided in some or all of the vacuum chamber 102.

A gas (e.g., argon) can be introduced into a gas inlet 112 at the first end of the nanoparticle source. The gas can be ionized and pass through a plasma region (e.g., nanoparticle-forming region) that is formed by a hollow or open region of the source 104. For example, positively charged ions in the gas can be accelerated by a negative potential at the targets 104A and knock out the atoms of the targets, leading to the formation of atom gas. Then the atom gas can condense to form nanoparticles. In some cases, the nanoparticles crystallize in the thermal environment of the plasma. “Plasma” can refer to the gas that contains formed nanoparticles. The magnetic field 110 can serve to control the movement of the positively charged ions and the formation of the nanoparticles. As a result, erosion of the outside of the source 104 can be minimized, such as at an outlet or second end of the source.

The source 104 includes targets 104A. In some cases, circular magnets 104B are coupled to (e.g., mounted on) the targets 104A or source 104. In some implementations, as shown in FIG. 1, the targets 104A are arranged lengthwise concentrically about axis c, forming form multi-tube source. For example, the circular magnets 104B can generate a magnetic field that controls the formation of the nanoparticles 106, and/or guides the nanoparticles 106 as they exit the source 104. In some implementations, the center element 104C of the source 104 can be a cylinder, and it can be surrounded by one or more tube targets arranged concentrically about the solid cylinder. In certain implementations, the center element 104C is a tube, and in some instances the center element 104C is a tube target.

In some implementations, the strength of the magnetic field (or H-field) can be in the range of 970 to 2000 Oe and can depend, for example, on the requirement of nanoparticle growth condition. Magnet selection can also depend on the particle size that is desired for the formed nanoparticles. Longer targets can increase the crystallization time and produce larger nanoparticles. Thicker magnets can increase the growth time and produce larger nanoparticles. In this example, the multi-tube target source 104A and the circular magnets 104B are made from tubes, which may be advantageous in terms of manufacturing the components, but in some implementations other shapes can be used.

FIG. 2 shows a cross-section 200 of the multi-surface nanoparticle deposition system in FIG. 1. The cross-section 200 shows tube magnets 104B forming extensions of the tube targets 104A and center element 104C. Tube magnets 104B generate the magnetic field 110 in a radially outward direction, in this example. The structure of the target and the magnet is segmented, in this example a segmented tube structure. A plasma region 202 is generated between two or more of the tube magnets 104B. By coupling the tube magnets 104B to the multi-tube target source 104A, the plasma region may be partially or entirely confined by the magnetic field in the gap regions between the two or more tube magnets. In some cases, the magnet is embedded in a cooling stage to inhibit overheating.

The targets 104A have the same potential on all tubes in this example. For example, having one anode and one cathode may not be suitable.

Generally, the properties and applications of fabricated nanoparticles will typically be determined by particle size and its crystal structure. For example, the field strength affects the intensity of the plasma, and the magnet length affects the length (L in the figure) of the plasma. The plasma's intensity and length, moreover, can determine the nanoparticles' size and phase. This indicates the plasma heating effect supplied by the magnet assembly.

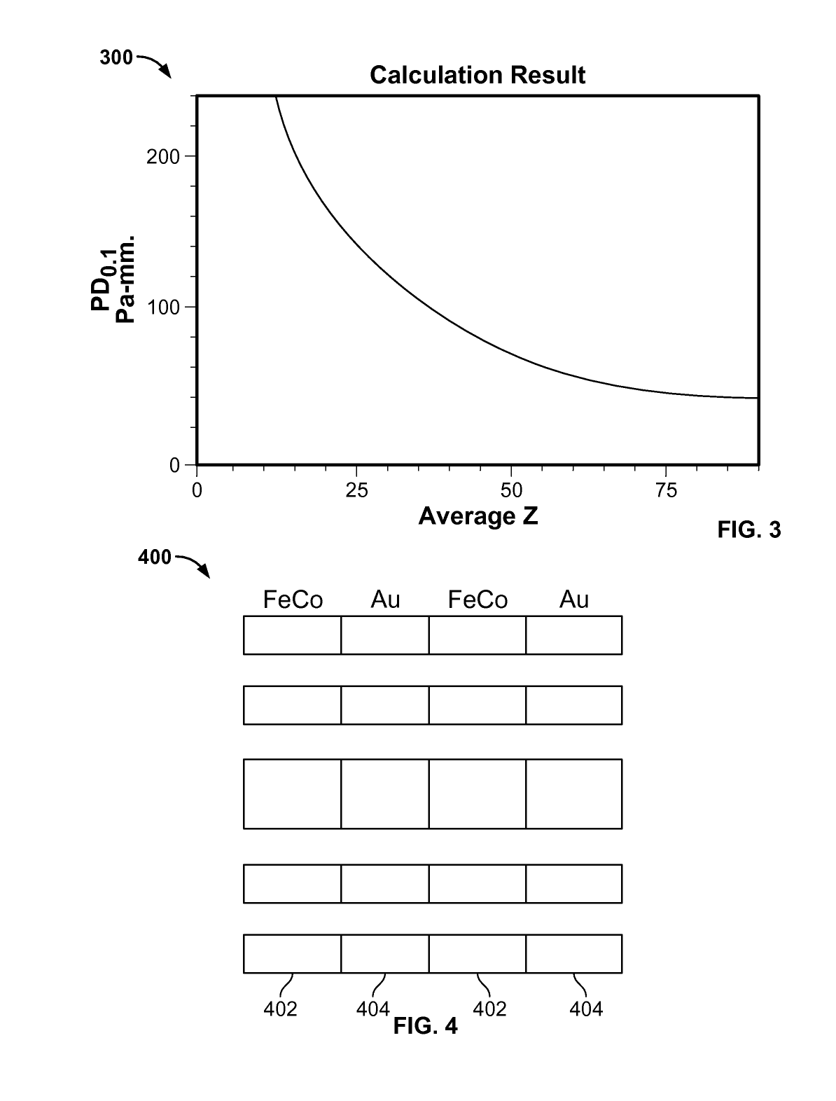

FIG. 3 shows an example of a pressure calculation 300. The calculation 300 illustrates the pressure requirement for nanoparticle nucleation and growth. P·D represents the product of pressure (P) and distance (D), and is shown as a function of the mean atomic mass (“Average Z”) of the sputtering gas and the sputtered atom. P·D_{0.1} indicates the pressure-distance product to reduce energy by 90%. In this example, the initial energy is approximately 20 eV.

Based on this calculation result, a P·D_{0.1} of 290 Pa-mm is obtained. In terms of distance, half of the gap between tube targets in the nanoparticle source was here used. In this example, D_{0.1}=2.5 mm, and P·D_{0.1}=290 Pa-mm, which gives P≧780 mTorr as the pressure required for formation of nanoparticles via sputtering.

Assuming that the sputtering current density is constant, the nanoparticle yield rate will be proportional to the area of the target's sputtered surface, for example according to the following equation:

R=(0.0557mg/hr/cm²)·S,

where R is the nanoparticle yield rate and S is the area of the target's sputtered surface.

Table 1 lists estimated nanoparticle yield rates using a multi-tube source having a target length of 4 cm, and four concentric tube targets. ID and OD stand for inner and outer diameters, respectively, of the tubes that define the gap. For example, the first gap is defined by the outer diameter of the smallest tube target, and by the inner diameter of the next smallest tube target. Because the ID−OD difference of adjacent targets is 1 cm, the gap distance used in this example is 5 mm.

TABLE 1
Estimated nanoparticle yield rates for a multi-tube source.

| | Size | Yield rate | Total yield |
|---|---|---|---|
| Gap | (cm) | (mg/hr) | rate (mg/hr) |
| First | OD 1 | 0.7 | 2.1 |
| | ID 2 | 1.4 | |
| Second | OD 3 | 2.1 | 7 |
| | ID 4 | 2.8 | |
| Third | OD 5 | 3.5 | 14.7 |
| | ID 6 | 4.2 | |

The numbers above can be contrasted with, for example, a single-tube source. Table 2 provides an estimated nanoparticle yield rate for a single-tube source with a target length of 4 cm.

TABLE 2
Estimated nanoparticle yield rate for a single-tube target source.

| | Yield rate | Total yield |
|---|---|---|
| Size (cm) | (mg/hr) | rate (mg/hr) |
| ID 0.5 | 0.35 | 0.35 |

The multi-tube source 104 can be manufactured with different dimensions. For example, a 5 mm gap is used in the above estimations. In some implementations, 2 mm may be a lower limit for the gap size, because with too small a gap it will be difficult for the material to exit the target. On the other hand, if too large a gap is used, its dimension begins to compete with the overall length of the target. For example, this can occur with 10-15 mm gaps, or larger. The target can have a ratio of gap distance, or ½|OD−ID| for adjacent targets to the target length of (i.e., an aspect ratio) of 1:1 or less (e.g., 1:2 or less, 1:4 or less, 1:8 or less, or 1:16 or less). In one example, with a 4 cm tube length and a 5 mm gap, the aspect ratio is 1:8.

The multi-tube target source 104A can be segmented. FIG. 4 shows an alternative cross-section 400 of the multi-surface nanoparticle deposition system in FIG. 1. Here, one or more segments 402 of a first material are located adjacent one or more segments 404 of a second material. For example, the first material can include FeCo-tube segment(s) and/or the second material can include Au-tube segment(s). For example, a segmented structure can be used in making FeCo—Au and/or any heterostructured nanoparticles.

The width of the segments 402 and/or 404 can be determined by the composition that is desired. For example, less Au as the shell and more FeCo as the core, can be obtained. The proportions of the segments 402 and 404 do not necessarily determine the ratio of materials in the nanoparticles. For example, the materials can have different deposition rates.

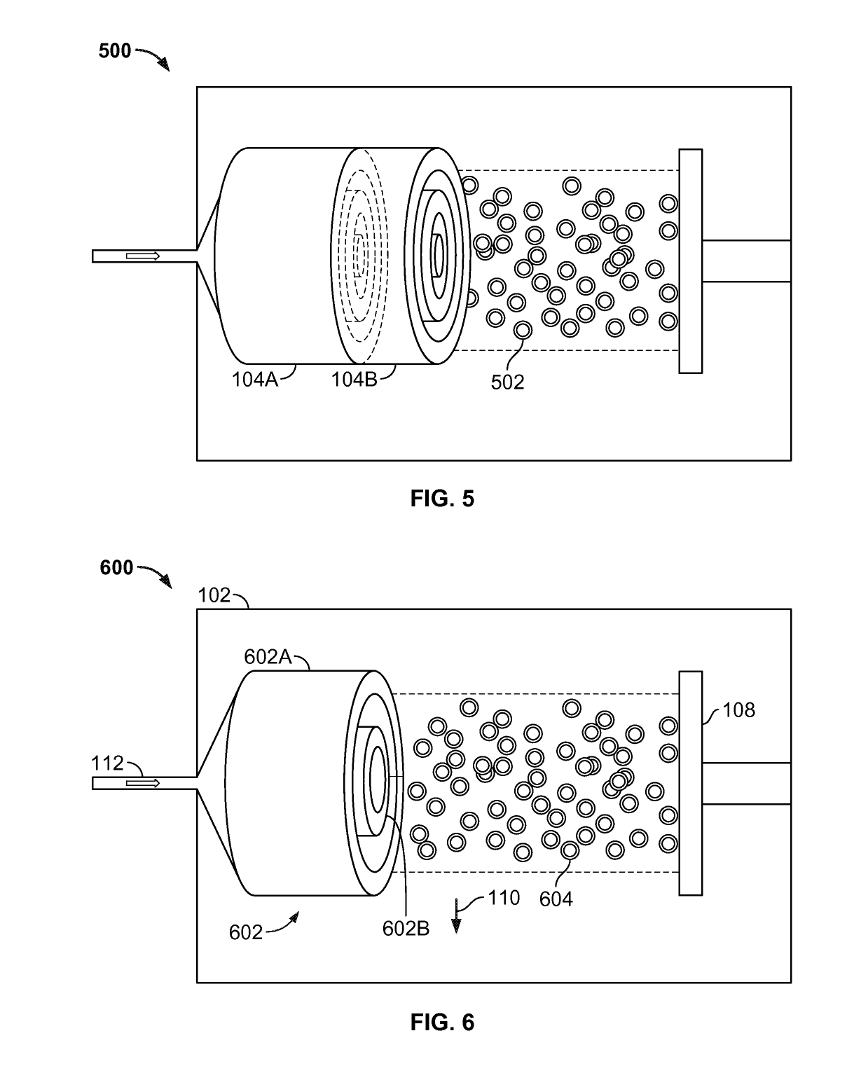

FIG. 5 shows a cross-sectional view of another example multi-surface nanoparticle deposition system 500. The system 500 may be similar to the system 100 (FIG. 1), at least in part. For example, the tube targets 104A can here include segments of a FeCo material and an Au material, as depicted in FIG. 4. Here, a core-shell structure nanoparticle 502 is generated. For example, the core-shell structure nanoparticle 502 can have a shell comprising Au and a core comprising FeCo.

FIG. 6 shows a cross-sectional view of another example multi-surface nanoparticle deposition system 600. The system 600 may be similar to the system 100 (FIG. 1), at least in part. For example, the system 600 can include the vacuum chamber 102, the nanoparticle collection substrate 108, the magnetic field 110 and the gas inlet 112. The system 600 can also include a source 602. Here, one or more tube targets 602A of a first material are concentrically located with respect to one or more tube targets 602B of a second material. For example, the first material can include FeCo, and/or the second material can include Au. The system 600 can generate a core-shell structure nanoparticle 604, for example with a shell comprising Au and a core comprising FeCo. The source 602 can include one or more circular magnets (not shown) for the tube source. For example, a double tube magnet can be used with the source 602.

In another implementation, the second material can include SiO₂. For example, this can be used to generate FeCo—SiO₂ core-shell structure nanoparticles.

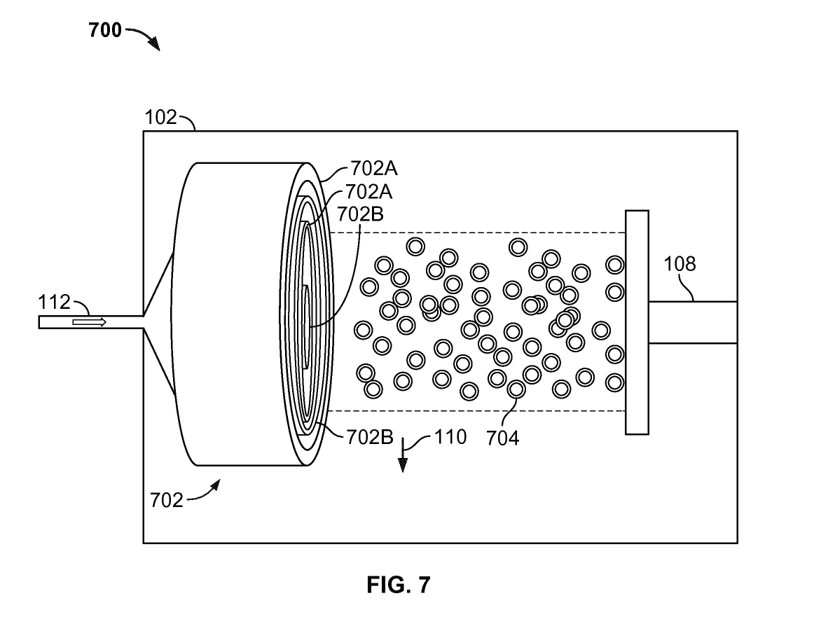

FIG. 7 shows a cross-sectional view of another example multi-surface nanoparticle deposition system 700. The system 700 may be similar to the system 100 (FIG. 1), at least in part. For example, the system 700 can include the vacuum chamber 102, the nanoparticle collection substrate 108, the magnetic field 110 and the gas inlet 112. The system 700 can also include a multi-tube source 702. Here, one or more tube targets 702A of a first material are concentrically located with respect to one or more tubes 702B of a second material. For example, the first material can include FeCo, and/or the second material can include Au. The system 700 can generate a core-shell structure nanoparticle 704, for example with a shell comprising Au and a core comprising FeCo. The system 700 can include one or more circular magnets (not shown) for the tube source. For example, a multi-tube magnet can be used with the multi-tube source 702.

In another implementation, the second material can include SiO₂. For example, this can be used to generate FeCo—SiO₂ core-shell structure nanoparticles.

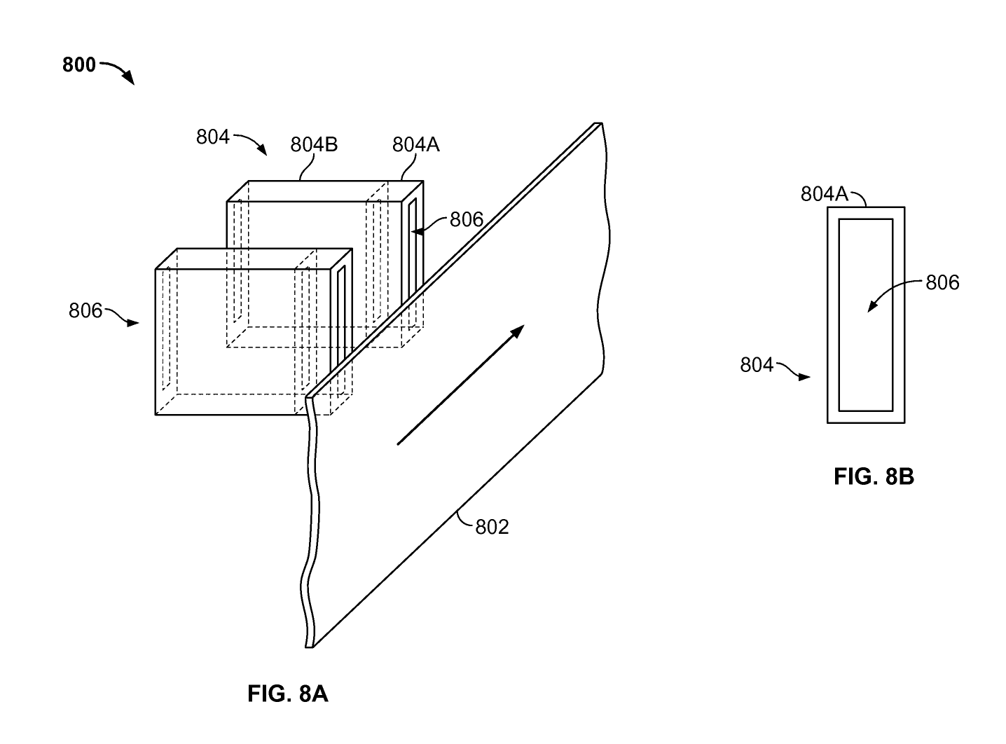

FIGS. 8A-B show an example of a slot configuration in a multi-surface nanoparticle deposition system 800. For example, the system 800 can be used for automatic nanoparticle generation and collection. Nanoparticles can be deposited on at least one substrate 802 that may be stationary or in motion. In some examples, the substrate is mounted on and continuously fed by an automatically-controlled roller system, such as within a collection chamber. Nanoparticles can be deposited on a portion of a long, flexible substrate material (e.g., a water-soluble polymer, etc.) that serves as the substrate 802. The substrate material can be mounted on one roller, and over time, another roller can slowly (but continuously) rotate, pulling deposited-upon portions of the substrate 802 from the first roller and exposing clean sections of the substrate material. In this example process that uses the long substrate on a roller system, the system can collect a significant amount of nanoparticles for a long time (e.g., hundreds of hours) without interruption to change the substrate.

The system 800 includes one or more nanoparticle sources 804. In some implementations, the nanoparticle source 804 can include one or more segments, such as 804A and B. For example, the segment 804A can be formed of one material (e.g., FeCo) and the segment 804B can be formed of a second material (e.g., Au or SiO₂.)

The nanoparticle source 804 has one or more openings 806. FIG. 8B shows a front view of the nanoparticle source 804 where the opening 806 is visible in the segment 804A. The opening 806 extends through the entire nanoparticle source 804 in this example, and the segments 804A and B can then have shapes similar or identical to each other. In operation, a magnet can be placed in front of the opening 806 (i.e., between the nanoparticle source 804 and the substrate 802. Inert gas can then be introduced at high pressure from the back of the nanoparticle source 804, wherein nanoparticles emerge through the opening 806, generally in the direction of the substrate 802.

The opening(s) 806 can have any suitable shape. In some implementations, the opening has a linear configuration. This can be useful for coating a continuous tape substrate that is used for collecting the deposited nanoparticles. For example, and without limitation, the opening can have a 5 mm opening width (e.g., “x-axis”) and an opening height of one or more centimeters (e.g., “y-axis.”) In some implementations, an opening width of several centimeters can provide good conditions for maintaining the plasma for sputtering. For example, the deposition rate proportional to the surface area of the deposition system can be increased. Using two or more openings 806 can further increase the deposition rate. For example, a source array of multiple nanoparticle sources 804 can be used.

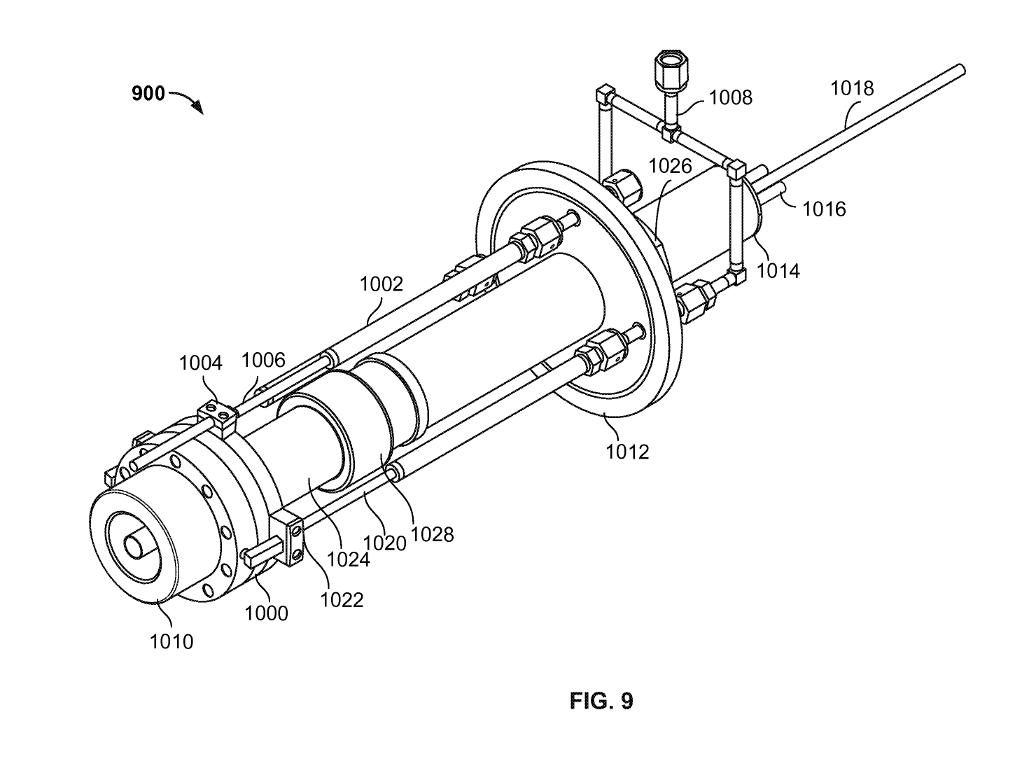

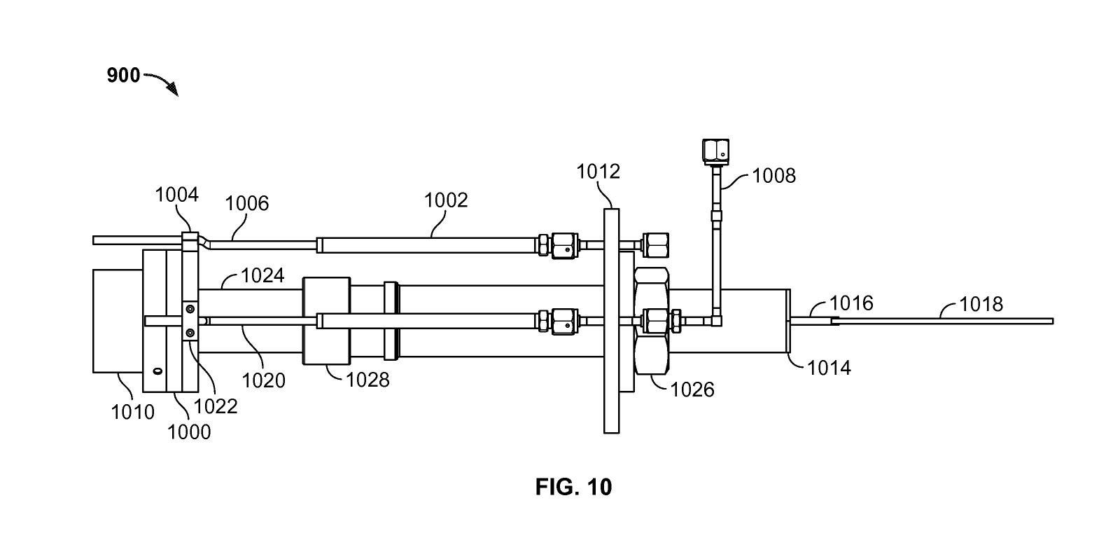

FIG. 9 shows an elevated view of another example of a multi-surface nanoparticle deposition system 900. FIG. 10 shows a side view of the multi-surface nanoparticle deposition system 900 in FIG. 9.

The multi-surface nanoparticle deposition system 900 includes an insulator 1000. For example, a 4.5″ insulator can be used.

The system 900 includes at least one tube 1002. For example, three telescoping tubes can be used.

The system 900 includes a vacuum tube brace assembly 1004. For example, any of the target and/or magnet configurations described herein can be used.

The system 900 includes a tube 1006. For example, a vacuum gauge tube can be used.

The system 900 includes a gas supply 1008. For example, a gas supply tube weldment can be used.

The system 900 includes a nanoparticle source 1010. The nanoparticle source may be any nanoparticle source described herein.

The system 900 includes a base plate weldment 1012. For example, any suitable shape and/or material can be used for the base plate weldment.

The system 900 includes at least one tubing support spacer 1014. For example, two tubing support spacers of any suitable shape and/or material can be used.

The system 900 includes at least one tube 1016. For example, two water extension tubes can be used.

The system 900 includes a power supply 1018. For example, any suitable power wire can be used for the power supply.

The system 900 includes at least one gas tube 1020. For example, two gas tubes of any suitable shape and/or material can be used.

The system 900 includes at least one gas tube support 1022. For example, any suitable shape and/or material can be used for the gas tube support.

The system 900 includes a movement weldment 1024. For example, any suitable shape and/or material can be used for the movement weldment.

The system 900 includes a nut 1026. For example, a 2″-12 nut can be used.

The system 900 includes a disconnect 1028. For example, a quick disconnect can be used.

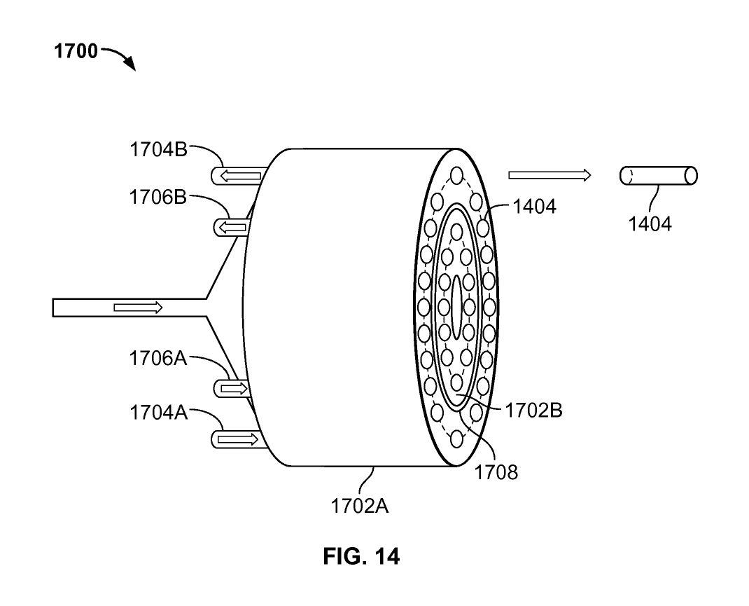

FIG. 14 shows an example of a multi-surface nanoparticle deposition system 1400 having a cylinder-shaped cooling block 1402. The system 1400 may be similar to the system 100 (FIG. 1), at least in part. For example, the system 1400 can include the vacuum chamber 102, a nanoparticle collection substrate, a magnetic field and the gas inlet 112.

The cooling block 1402 and multiple tube targets 1404 form a multi-tube source 1406. The targets 1404, one of which is shown individually for clarity, are tube sputtering targets made from a suitable material, including, but not limited to, FeCo and Au. That is, the cooling block has multiple openings, and a tube sputtering target can be inserted in each opening. In some implementations, each tube sputtering target behaves in the same or a similar way as a single-tube nanoparticle deposition source. For example, the total deposition rate of the multi-tube source may be equal to the deposition rate of a single source multiplied by the number of openings.

The targets 1404 can be arranged on the cooling block 1402 in any suitable orientation or location. In some implementations, the targets are placed in a regular pattern. For example, the targets 1404 here form a first ring 1408A and a second ring 1408B positioned concentrically about an axis that extends from a first end of source 1406 (e.g., the inlet) to a second end of the source (e.g., the outlet). The system 1400 can include one or more circular magnets (not shown) coupled to or positioned proximate the tube targets. For example, a multi-tube magnet can be used with the multi-tube source 1406.

The multi-surface nanoparticle deposition system 1400 can be cooled in one or more ways. In some implementations, at least one fluid can be brought in thermal contact with some or all of the targets 1404. Here, for example, the cooling block 1402 includes one fluid inlet 1410A and at least one fluid outlet 1410B, with a cooling chamber therebetween in the cooling block. Any suitable fluid can be used, including, but not limited to, water.

As with other nanoparticle sources described herein, an aspect ratio of at least one of the targets is 1.1 or less. For tube targets such as tube target 1404, the aspect ratio is calculated as the ratio of the diameter of the opening to the length of the target.

Table 3 lists estimated nanoparticle deposition rates for a system in which each tube target has diameter 0.5 cm and length 4 cm. For example, such estimation can be relevant to the targets 1404, such as in an integrated multi-surface nanoparticle deposition system using cylindrical configuration (e.g., system 1400).

TABLE 3
Estimated nanoparticle deposition rates.

| | | Estimated |
|---|---|---|
| Radius | Total number | deposition rate |
| (cm) | of tube targets | (mg/hr) |
| 1 | 1 | 0.35 |
| 3 | 5 | 1.75 |
| 5 | 13 | 4.55 |
| 7 | 25 | 8.75 |
| 9 | 41 | 14.35 |
| 11 | 61 | 21.35 |
| 13 | 86 | 30.1 |
| 15 | 115 | 40.25 |
| 17 | 148 | 51.8 |
| 19 | 185 | 64.75 |
| 21 | 226 | 79.1 |
| 23 | 272 | 95.2 |
| 25 | 322 | 112.7 |
| 27 | 376 | 131.6 |
| 29 | 434 | 151.9 |
| 31 | 496 | 173.6 |
| 33 | 563 | 197.05 |
| 35 | 634 | 221.9 |
| 37 | 709 | 248.15 |
| 39 | 788 | 275.8 |
| 41 | 871 | 304.85 |
| 43 | 958 | 335.3 |
| 45 | 1050 | 367.5 |
| 47 | 1146 | 401.1 |
| 49 | 1246 | 436.1 |
| 51 | 1350 | 472.5 |

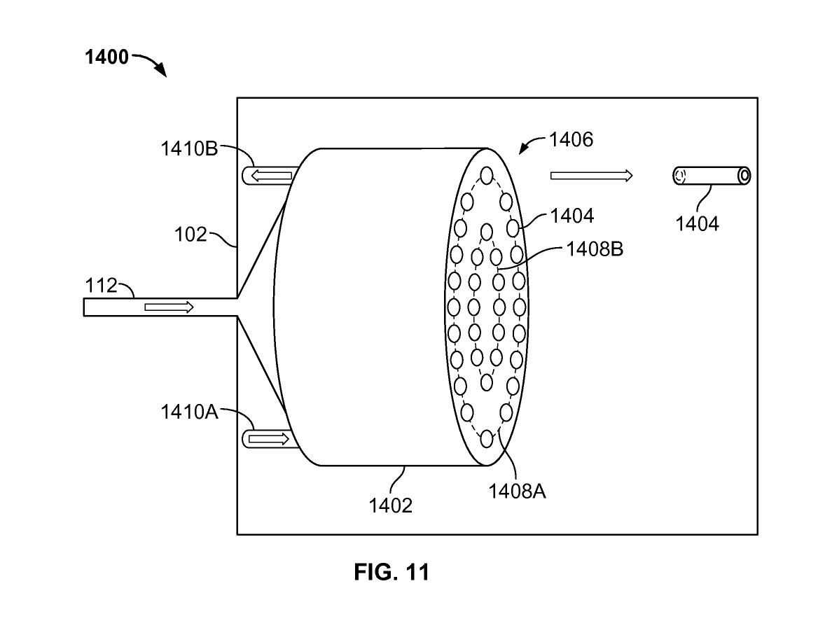

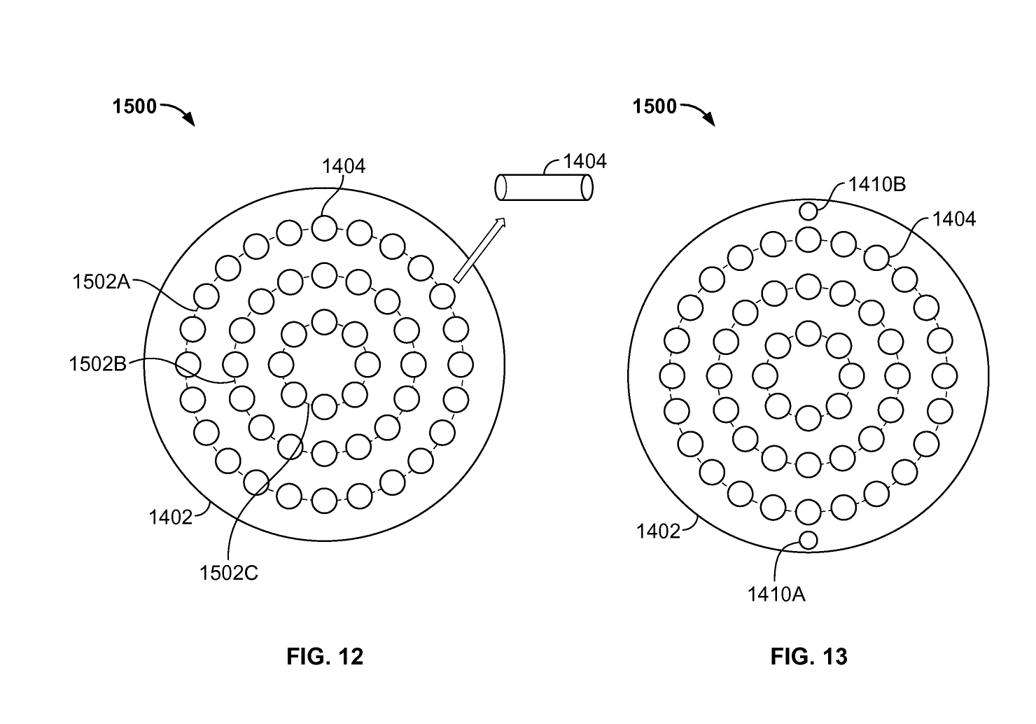

FIG. 12 shows a front view of a multi-surface nanoparticle deposition system 1500. The system 1500 can be and operate similar to the system 1400 in FIG. 11, but the system 1500 in this example includes three groups 1502A-C of targets 1404. The groups 1502A-C can be distributed over one or more surfaces of the cooling block 1402.

FIG. 13 shows a rear view of the multi-surface nanoparticle deposition system 1500 in FIG. 12. In this example, the cooling block 1402 includes the fluid inlet 1410A and the fluid outlet 1410B.

FIG. 14 shows an example of a multi-surface nanoparticle deposition system 1700 having multiple cooling blocks 1702A and 1702B. Each of the multiple cooling blocks can have at least one cooling system. For example, the cooling block 1702A here has a fluid inlet 1704A and the fluid outlet 1704B, and the cooling block 1702B here has a fluid inlet 1706A and the fluid outlet 1706B. Each cooling block can be subjected to a fluid flow that is the same as, or different from, the flow(s) of any other cooling block(s). For example, the fluid flow can be proportional to the volume of the cooling block and/or to the number of targets 1404 in that cooling block.

One or more spaces 1708 can be formed between adjacent cooling blocks. For example, the space 1708 can facilitate energy dissipation from the cooling block(s) to the environment, and/or facilitate thermal isolation between two or more cooling blocks. In some implementations, the space(s) 1708 can be partially or completely filled with a thermally insulating material. In this example, the space 1708 is essentially cylindrical.

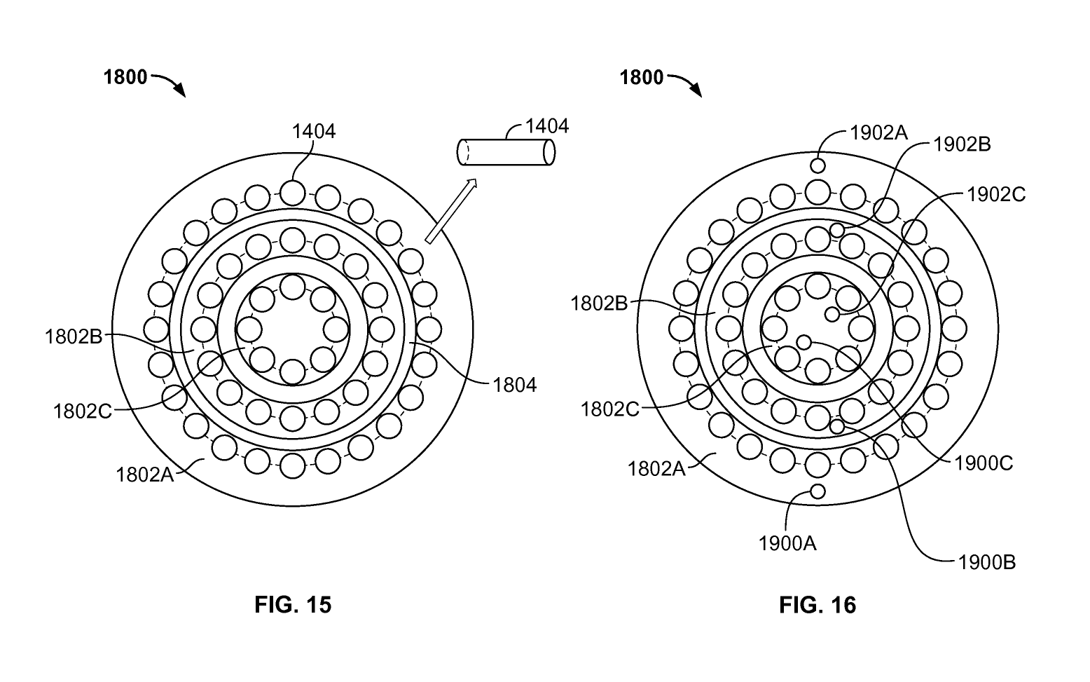

FIG. 15 shows a front view of a multi-surface nanoparticle deposition system 1800 having multiple cooling blocks 1802A-C. In some implementations, each of the cooling blocks can have at least one cooling system. For example, fluid inlet(s) and outlet(s) can be provided for each cooling system. One or more spaces 1804 can be formed between adjacent cooling blocks. In this example, the space 1804 is essentially cylindrical and corresponds to the placement of the targets 1404.

FIG. 16 shows a rear view of the multi-surface nanoparticle deposition system 1800 in FIG. 15. Each of the cooling blocks 1802A-C can have at least one cooling system. For example, the cooling block 1802A here has a fluid inlet 1900A and a fluid outlet 1902A, the cooling block 1802B here has a fluid inlet 1900B and a fluid outlet 1902B, and the cooling block 1802C here has a fluid inlet 1900C and a fluid outlet 1902C.

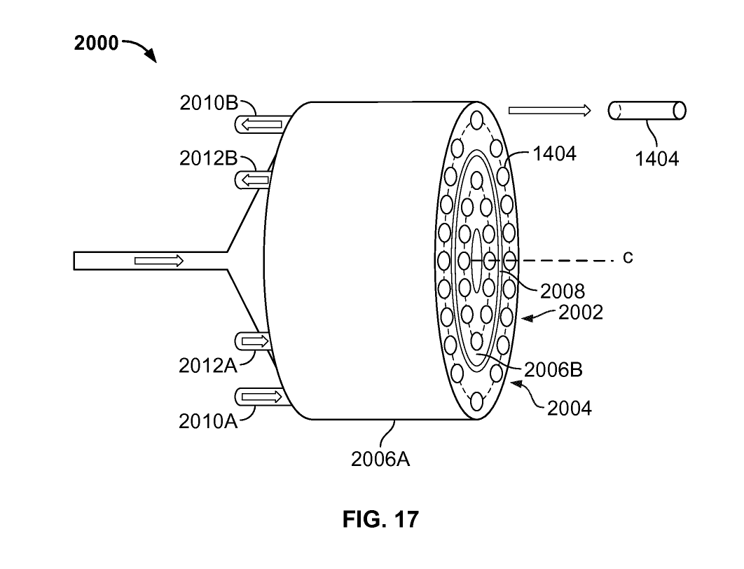

FIG. 17 shows an example of a multi-surface nanoparticle deposition system 2000 having a multi-surface target 2002 and a multi-tube target 2004 arranged about an axis c. The multi-surface target 2002 can include multiple surfaces, such as tube 2006A and tube 2006B. In some implementations, the tubes 2006A-B operate similarly or identically to the tubes 602A and 602B in FIG. 6. That is, a space 2008 can be formed between the multiple surfaces and serve as a sputtering target. For example, each of the tubes 2006A-B can be made of a different material.

The multi-tube target 2004 can include multiple targets, such as the targets 1404. The targets 1404 can be arranged on the multi-tube target 2004 in any suitable orientation or location. The targets can be placed in a regular pattern, for example in essentially circular arrangement about axis c. In some implementations, the multi-surface target 2002 is considered a large tube sputtering target and the targets 1404 are considered a small tube sputtering target.

The multi-surface target 2002 and/or the multi-tube target 2004 can be provided with cooling. In some implementations, the tube 2006A has fluid inlet 2010A and fluid outlet 2010B, and the tube 2006B has fluid inlet 2012A and fluid outlet 2012B. In some implementations, one or more targets 1404 can be placed in the space 2008.

Table 4 lists estimated nanoparticle deposition rates for a system in which each tube target has diameter 0.5 cm and length 4 cm. For example, such estimation can be relevant to the targets 1404, such as in an integrated multi-surface nanoparticle deposition system using cylindrical configuration (e.g., system 2000).

TABLE 4
Estimated nanoparticle deposition rates.

| | | | Estimated | |
|---|---|---|---|---|
| | Total | Estimated | deposition | |
| | number | deposition rate of | rate of big | Estimated total |
| Radius | of tube | small tube target | tube target | deposition rate |
| (cm) | targets | (mg/hr) | (mg/hr) | (mg/hr) |
| 1 | 1 | 0.35 | 0 | 0.35 |
| 4 | 7 | 2.45 | 4.2 | 6.65 |
| 7 | 19 | 6.65 | 16.8 | 23.45 |
| 10 | 37 | 12.95 | 37.8 | 50.75 |
| 13 | 62 | 21.7 | 67.2 | 88.9 |
| 16 | 93 | 32.55 | 105 | 137.55 |
| 19 | 130 | 45.5 | 151.2 | 196.7 |
| 22 | 173 | 60.55 | 205.8 | 266.35 |
| 25 | 223 | 78.05 | 268.8 | 346.85 |
| 28 | 279 | 97.65 | 340.2 | 437.85 |
| 31 | 341 | 119.35 | 420 | 539.35 |
| 34 | 410 | 143.5 | 508.2 | 651.7 |
| 37 | 485 | 169.75 | 604.8 | 774.55 |
| 40 | 566 | 198.1 | 709.8 | 907.9 |
| 43 | 653 | 228.55 | 823.2 | 1051.75 |
| 46 | 747 | 261.45 | 945 | 1206.45 |
| 49 | 847 | 296.45 | 1075.2 | 1371.65 |
| 52 | 953 | 333.55 | 1213.8 | 1547.35 |

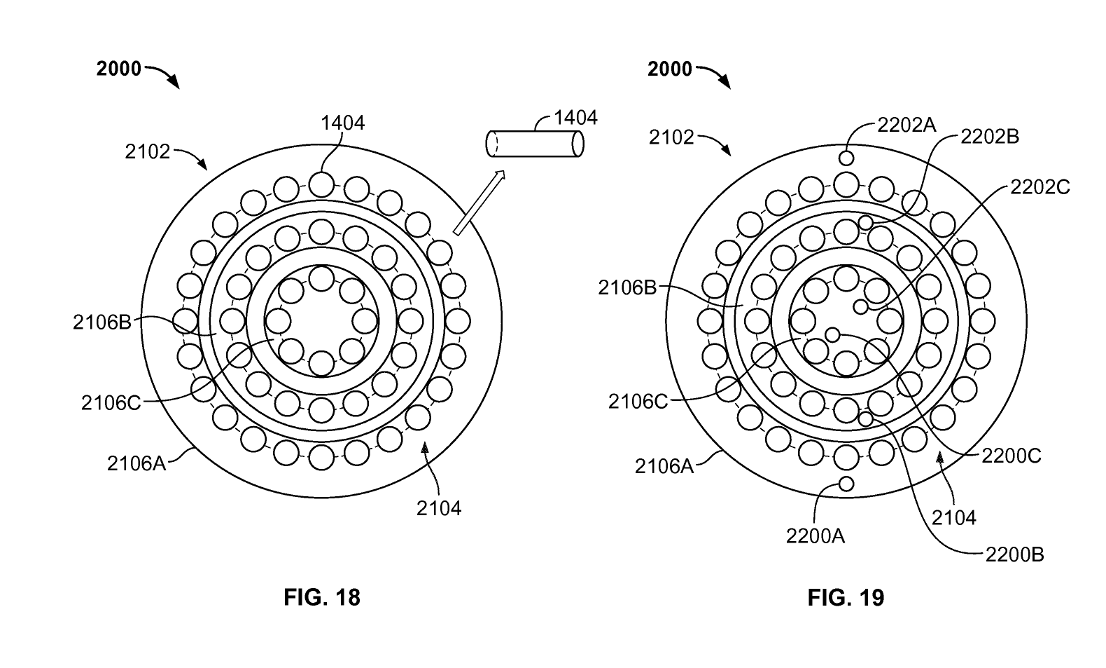

FIG. 18 shows a front view of the multi-surface nanoparticle deposition system 2000 having a multi-surface target 2102 and a multi-tube target 2104. Some details of the system 2000 visible in this and the next figure are omitted in FIG. 17 for simplicity, and vice versa. In some implementations, the multi-surface target 2102 includes tubes 2106A-C. For example, each of the tubes can have at least one cooling system. The multi-tube target 2104 can have targets, such as the targets 1404 organized in any suitable way, for example in essentially circular configuration.

FIG. 19 shows a rear view of the multi-surface nanoparticle deposition system 2000 in FIG. 17. The multi-surface target 2102 and/or the multi-tube target 2104 can be provided with cooling. In some implementations, the tube 2106A has fluid inlet 2200A and fluid outlet 2202A, the tube 2106B has fluid inlet 2200B and fluid outlet 2202B, and the tube 2106C has fluid inlet 2200C and fluid outlet 2002C.

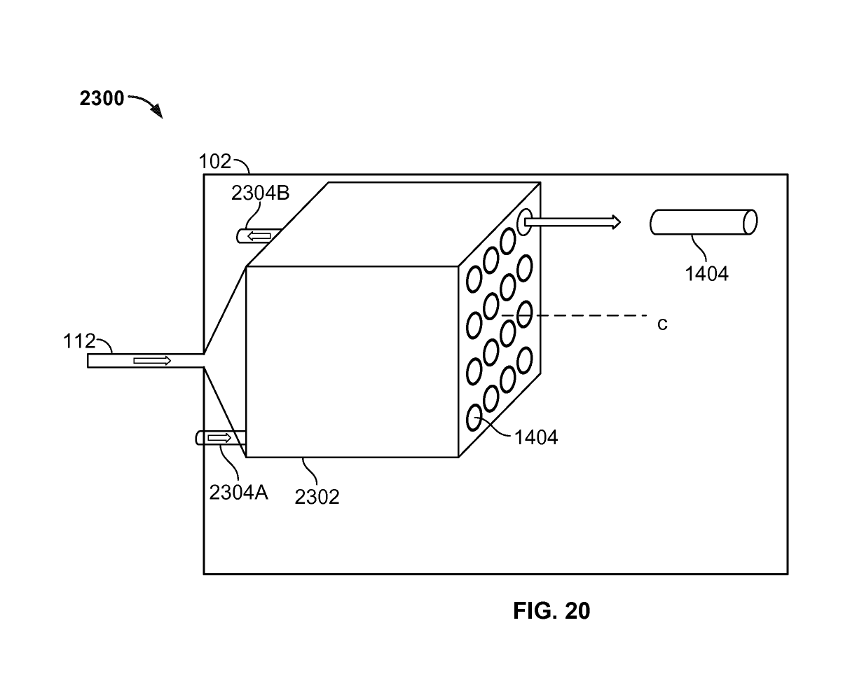

FIG. 20 shows an example of a multi-tube nanoparticle deposition system 2300 having a cube-shaped cooling block 2302. In this implementation, the cooling block 2302 is non-cylindrical. For example, the cooling block can have a cuboid shape. The system 2300 may in other regards be similar to the system 100 (FIG. 1), at least in part. For example, the system 1400 can include the vacuum chamber 102, a nanoparticle collection substrate, a magnetic field and the tube entrance 112. The targets 1404, one of which is shown individually for clarity, are tube sputtering targets made from a suitable material, including, but not limited to, FeCo and Au. That is, the cooling block has multiple openings, and a tube sputtering target can be inserted in each opening. The targets 1404 can be arranged on the cooling block 1402 in any suitable orientation or location. In some implementations, each tube sputtering target behaves in the same or a similar way as a single-tube nanoparticle deposition source. The tube targets are arranged about axis c.

The multi-surface nanoparticle deposition system 2300 can be cooled in one or more ways. In some implementations, at least one fluid can be brought in thermal contact with some or all of the targets 1404. Here, for example, the cooling block 2302 includes one fluid inlet 2304A and at least one fluid outlet 2304B. Any suitable fluid can be used, including, but not limited to, water.

Table 5 lists estimated nanoparticle deposition rates for a system in which each tube target has diameter 0.5 cm and length 4 cm. For example, such estimation can be relevant to the targets 1404, such as in an integrated multi-tube nanoparticle deposition system using a cube configuration (e.g., having a square shape in the front, such as system 2300).

TABLE 5
Estimated nanoparticle deposition rates.

| | | Estimated |
|---|---|---|
| Radius | Total number | deposition rate |
| (cm) | of tube targets | (mg/hr) |
| 3 | 1 | 0.35 |
| 6 | 4 | 1.4 |
| 9 | 9 | 3.15 |
| 12 | 16 | 5.6 |
| 15 | 25 | 8.75 |
| 18 | 36 | 12.6 |
| 21 | 49 | 17.15 |
| 24 | 64 | 22.4 |
| 27 | 81 | 28.35 |
| 30 | 100 | 35 |
| 33 | 121 | 42.35 |
| 36 | 144 | 50.4 |
| 39 | 169 | 59.15 |
| 42 | 196 | 68.6 |
| 45 | 225 | 78.75 |
| 48 | 256 | 89.6 |
| 51 | 289 | 101.15 |
| 54 | 324 | 113.4 |
| 57 | 361 | 126.35 |
| 60 | 400 | 140 |
| 63 | 441 | 154.35 |
| 66 | 484 | 169.4 |
| 69 | 529 | 185.15 |
| 72 | 576 | 201.6 |
| 75 | 625 | 218.75 |
| 78 | 676 | 236.6 |
| 81 | 729 | 255.15 |
| 84 | 784 | 274.4 |
| 87 | 841 | 294.35 |
| 90 | 900 | 315 |
| 93 | 961 | 336.35 |
| 96 | 1024 | 358.4 |
| 99 | 1089 | 381.15 |
| 102 | 1156 | 404.6 |

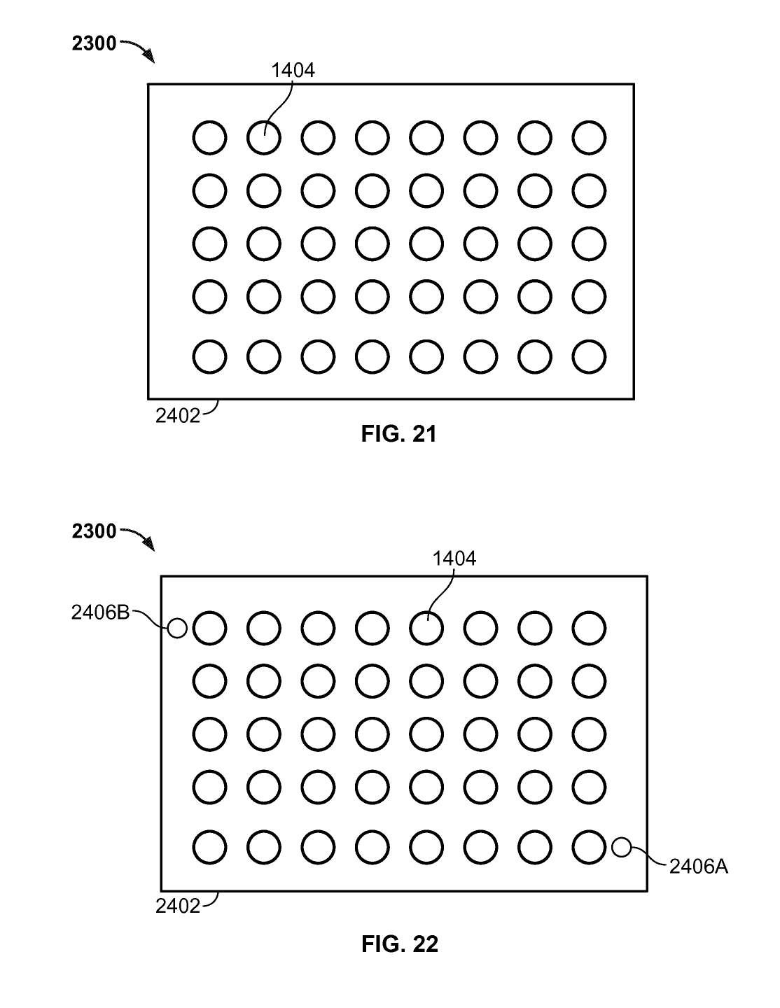

FIG. 21 shows a front view of the multi-surface nanoparticle deposition system 2300. Some details of the system 2300 visible in this and the next figure are omitted in FIG. 21 for simplicity, and vice versa. The system 2300 includes a single cooling block 2402 that has mounted therein the targets 1404. In some implementations, the cooling block has essentially a cuboid shape. For example, the targets 1404 can be organized in a pattern on at least one side of the cooling block.

FIG. 22 shows a rear view of the multi-surface nanoparticle deposition system 2300 in FIG. 20. The cooling block 2402 can include one or more cooling systems for the targets 1404. Here, the cooling block includes a fluid inlet 2406A and a fluid outlet 2406B. In some implementations, a multi-surface approach can also or instead be used. For example, the system 2400 can be provided with two or more larger-scale surfaces in addition to the targets 1404 (in analogy with the tubes 2006A and 2006B in FIG. 17).

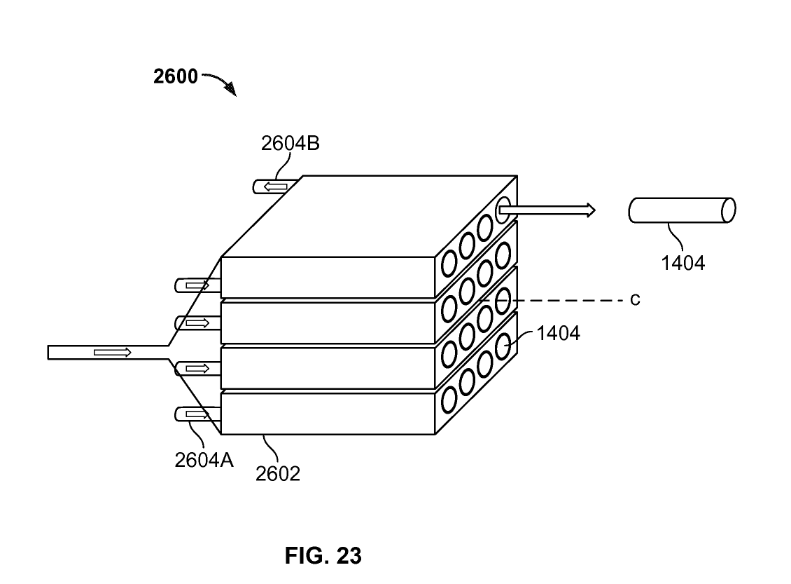

FIG. 23 shows an example of a multi-surface nanoparticle deposition system 2600 having multiple cube-shaped cooling blocks 2602. In some implementations, each of the cooling blocks can have at least one cooling system. For example, each of the cooling blocks can have at least one fluid inlet 2604A and at least one fluid outlet 2604B. The cooling blocks 2602 can have any suitable shape, including, but not limited to, a cuboid shape.

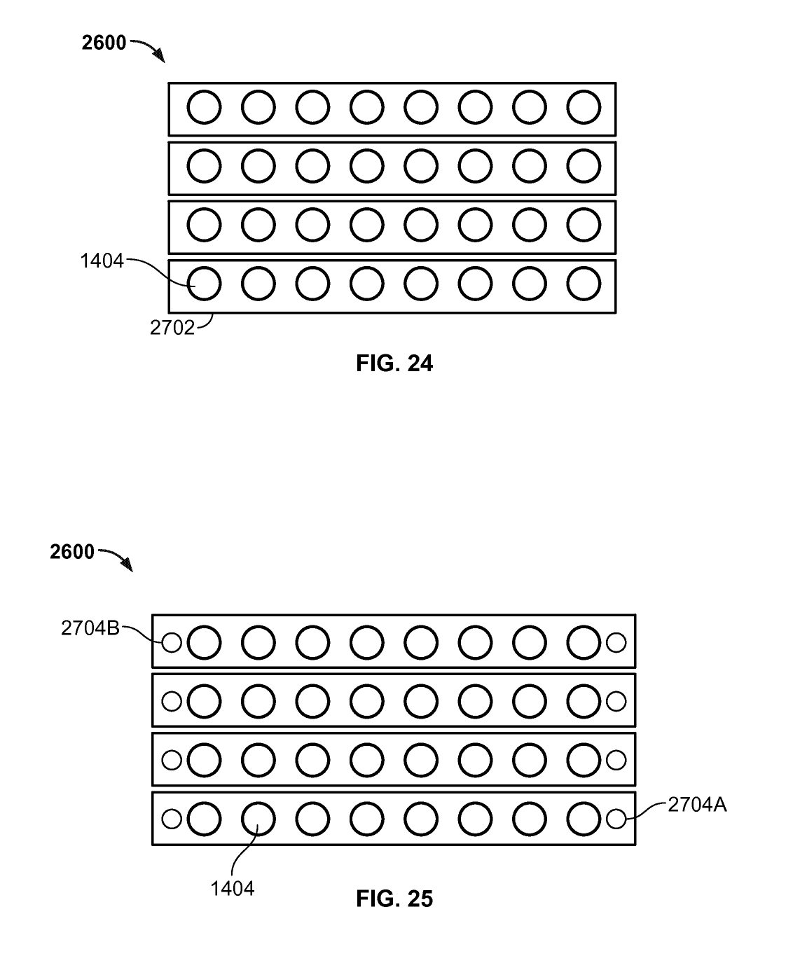

FIG. 24 shows a front view of the multi-surface nanoparticle deposition system 2600. Some details of the system 2600 visible in this and the next figure are omitted in FIG. 23 for simplicity, and vice versa. In the system 2600, each cooling block 2702 can include one or more of the targets 1404, for example in a linear arrangement, arranged about axis c shown in FIG. 23. For example, the cooling block can have a cuboid shape.

FIG. 25 shows a rear view of the multi-surface nanoparticle deposition system 2600 in FIG. 23. The cooling block 2702 can include one or more cooling systems for the targets 1404. Here, the cooling block includes a fluid inlet 2704A and a fluid outlet 2704B.

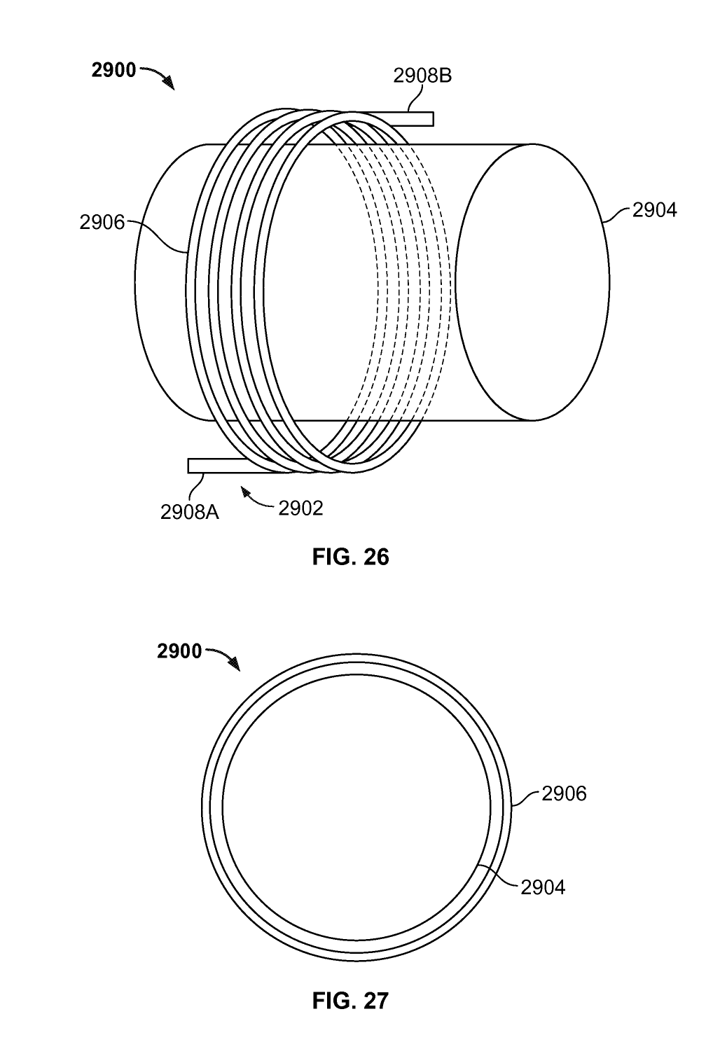

FIG. 26 shows an example of a multi-surface nanoparticle deposition system 2900 having a magnetic field supply 2902. The magnetic field supply can enclose a source 2904, which for example can be an integrated source that includes tube targets and one or more cooling blocks. The cooling block, which is here schematically illustrated as a cylinder, can be made of one or more relatively soft magnetic materials, including, but not limited to, Fe, Co, Ni, FeSi, FeCoNi, to name just a few examples.

The magnetic field supply can form one or more coils 2906 around the source 2904. For example, the coil can have at least one current inlet 2908A and at least one current outlet 2908B. In some implementations, a combination of a cooling block and coil(s) can behave as an electromagnet which can generate a large magnetic field inside each tube target. The arrangement using a coil (e.g., the magnetic field supply 2902) can be used with some or all systems described herein.

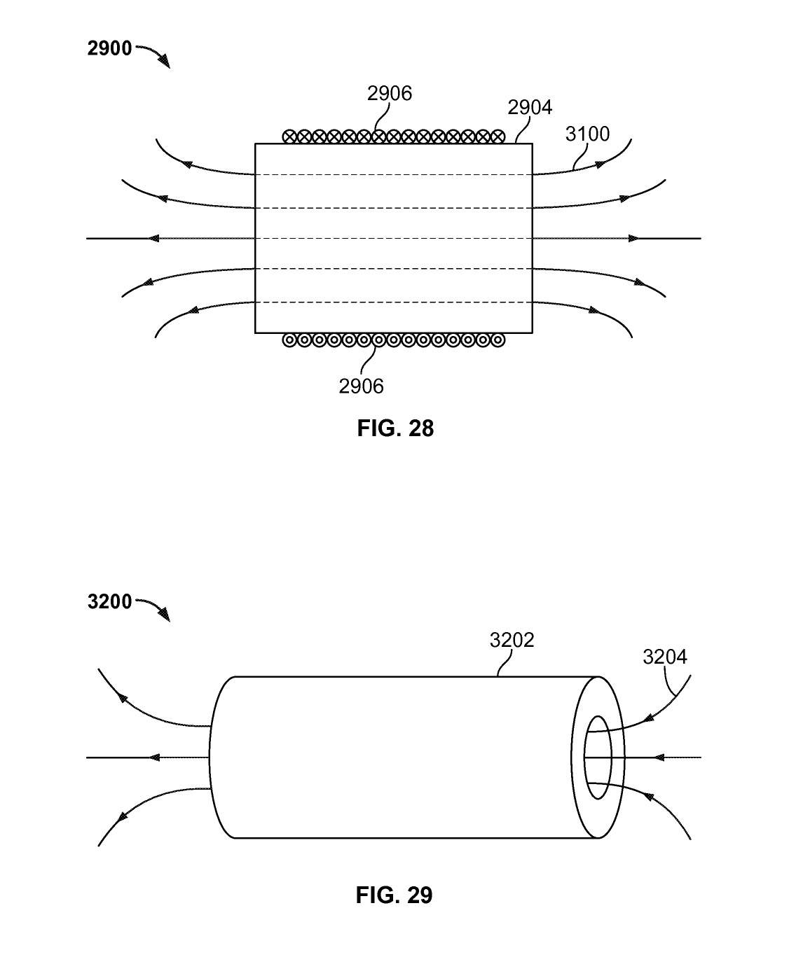

FIG. 27 shows a front view of the multi-surface nanoparticle deposition system 2900 in FIG. 28. Here, the coil 2906 surrounds the source 2904, which can for example be an integrated source of at least one cooling block and multiple tube targets.

FIG. 28 shows a cross-section view of the multi-surface nanoparticle deposition system 2900 in FIG. 26. Here, a magnetic field 3100 is being generated using the coils 2906. In at least part of the cooling block 2904, the magnetic field 3100 may be essentially homogeneous.

FIG. 29 shows an example of a magnetic field configuration 3200 for a tube target 3202. For example, the tube target can be any of the tube targets described in other examples in this document. Here, a magnetic field 3204 is formed in and around the tube target. The magnetic field can be generated in any suitable way, including, but not limited to, using the magnetic field supply 2902 in FIG. 26. In at least part of the tube target 3202, the magnetic field 3204 may be essentially homogeneous.

In some implementations, one or more rotating magnetron sources can be used for nanoparticle deposition. For example, rotating magnets or rotating electromagnets can provide a magnetic field to different areas of a single target or to multiple targets such as targets arranged in a circle.

In some implementations, multi-source integrated nanoparticle deposition system can funnel particles of different types through a magnetic field to a substrate or compression die. As a result, particles having different characteristics can be manufactured and collected simultaneously.

A number of implementations have been described. Nevertheless, it will be understood that various modifications may be made without departing from the spirit and scope of this disclosure.

What is claimed is:

1. A nanoparticle source comprising:
a first end comprising an inlet configured to receive a flow of gas;
a second end comprising an outlet through which nanoparticles exit the nanoparticle source; and
two or more targets spaced apart and arranged about an axis extending from the first end to the second end, wherein at least one of the targets is hollow and the inlet is arranged to direct a flow of the gas through the hollow target, between at least two of the targets, or both, the gas thereby impacting the targets and releasing atoms therefrom and through the second end.

2. The nanoparticle source of claim 1, wherein the aspect ratio of at least one of the targets is 1:1 or less, 1:2 or less, 1:4 or less, 1:6 or less, 1:8 or less, or 1:16 or less.

3. The nanoparticle source of claim 1, further comprising a permanent magnet or electromagnet proximate the second end of the nanoparticle source, wherein the magnet provides a magnetic field that controls movement of the gas through the nanoparticle source.

4. The nanoparticle source of claim 3, wherein the magnet is coupled to an end of one of the targets.

5. The nanoparticle source of claim 4, wherein the magnet forms an extension of the target to which it is coupled.

6. The nanoparticle source of claim 5, wherein the magnet is a circular magnet having the same inner diameter and outer diameter as the target to which the magnet is coupled.

7. The nanoparticle source of claim 4, wherein the magnet is a circular magnet, and an inner diameter of the circular magnet is greater than or equal to the outer diameter of the target to which the circular magnet is coupled.

8. The nanoparticle source of claim 4, wherein the magnet comprises samarium cobalt, neodymium cobalt, or a combination thereof.

9. The nanoparticle source of claim 1, wherein the targets are arranged concentrically about the axis.

10. The nanoparticle source of claim 1, wherein the targets define an opening therebetween, and the inlet is arranged to deliver a flow of the gas through the opening and toward the second end.

11. The nanoparticle source of claim 1, wherein one of the targets is a cylinder centered lengthwise about the axis.

12. The nanoparticle source of claim 1, wherein one or more of the targets are tube targets.

13. The nanoparticle source of claim 1, wherein at least two of the targets comprise different target materials.

14. The nanoparticle source of claim 1, wherein at least one of the targets comprises segments of two or more different target materials.

15. The nanoparticle source of claim 13 or claim 14, wherein the target materials comprise Au, Ag, Fe, FeCo, Gd, SiO₂, Si, C, N, Al, Mg, or a combination thereof.

16. The nanoparticle source of claim 1, further comprising a cooling block, and wherein at least some of the targets are positioned in openings defined by the cooling block.

17. The nanoparticle source of claim 16, wherein a surface of the cooling block comprises a target.

18. The nanoparticle source of claim 17, wherein the target comprises Fe, Co, Ni, Si, Ti, N, Mg, C, or any combination thereof.

19. The nanoparticle source of claim 16, wherein the cooling block defines a cooling chamber configured to receive a cooling fluid.

20. The nanoparticle source of claim 16, wherein the targets positioned in openings defined by the cooling block are tube targets.

21. The nanoparticle source of claim 16, wherein the cooling block is rectangular.

22. The nanoparticle source of claim 21, further comprising one or more additional rectangular cooling blocks and additional tube targets, wherein each additional rectangular cooling block defines additional openings, the additional tube targets are positioned in the additional openings, and each additional rectangular cooling block is positioned adjacent at least one other rectangular cooling block.

23. The nanoparticle source of claim 16, wherein the cooling block is cylindrical, and the tube targets positioned in the openings defined by the cooling block are arranged in one or more concentric rings about the axis.

24. The nanoparticle source of claim 23, further comprising one or more additional tubular cooling blocks and additional tube targets, wherein:
each additional tubular cooling block is arranged concentrically about the cylindrical cooling block,
each additional cooling block defines additional openings, and
the additional tube targets are positioned in the additional openings and arranged in one or more concentric rings about the axis.

25. The nanoparticle source of claim 16, wherein the cooling block is tubular, and the tube targets positioned in the openings defined by the cooling block are arranged in a ring about the axis, and further comprising one or more additional tubular cooling blocks and additional tube targets, wherein:
each additional tubular cooling block is arranged concentrically about the tubular cooling block,
each additional cooling block defines additional openings, and
the additional tube targets are positioned in the additional openings and arranged in one or more concentric rings about the central axis.

26. The nanoparticle source of claims 21, 24, or 25, wherein the cooling block and the one or more additional cooling blocks are independently cooled.

27. The nanoparticle source of any one of the above claims, further comprising a coil positioned about the nanoparticle source, wherein the coil comprises a current inlet and a current outlet and is configured to generate a magnetic field in each of the targets.

28. Nanoparticles formed by the nanoparticle source of any one of the above claims.

29. The nanoparticles of claim 28, wherein the nanoparticles are homogenous.

30. The nanoparticles of claim 28, wherein the nanoparticles comprise a core and a shell.

31. The nanoparticles of claim 30, wherein the core and the shell comprise different materials.

32. The nanoparticles of claim 31, wherein the materials comprise Fe, FeCo, Au, SiO₂, Fe₅Si₃, Fe₃Si, Fe₁₆N₂, FeN, or a combination thereof.

33. Use of the nanoparticle source of any of claims 1-27 to form nanoparticles.

34. A method of forming nanoparticles, the method comprising:
introducing a sputtering gas into the nanoparticle source of any of claims 1-27 via the inlet;
ionizing the gas;
passing the ionized gas through a plasma region in the opening(s) between adjacent targets or through the targets to liberate atoms from the target, thereby yielding a gas comprising the liberated atoms; and
condensing the gas comprising the liberated atoms to yield nanoparticles.
